(19) United States
(12) Patent Application Publication
(10) Pub. No.: US 2023/0209817 A1
(43) Pub. Date: Jun. 29, 2023

(54) SEMICONDUCTOR MEMORY DEVICE, METHOD FOR FABRICATING SEMICONDUCTOR MEMORY DEVICE, SEMICONDUCTOR INTEGRATED CIRCUIT AND SEMICONDUCTOR MEMORY INTEGRATED CIRCUIT

(71) Applicant: LAPIS SEMICONDUCTOR CO., LTD., Kanagawa (JP)

(72) Inventor: KENICHIRO KUSANO, KANAGAWA (JP)

(21) Appl. No.: 18/085,730

(22) Filed: Dec. 21, 2022

(30) Foreign Application Priority Data
Dec. 24, 2021 (JP) 2021-211455

(51) Int. Cl. H10B 20/00

(52) U.S. Cl. CPC H01L 27/1126

(57) ABSTRACT

A semiconductor memory device includes a semiconductor region including an active region for a memory transistor and plural depressions for trench isolation, insulating regions respectively provided at the depressions, a gate electrode and a gate insulation film. The gate electrode extends in a direction from one to the other of a first insulating region and second insulating region, and passes over the active region. The gate insulation film is provided between the gate electrode and the active region provided between the first and second insulating regions. The first and second insulating regions includes an adjacent region and a distant region. The distant region is adjacent to the adjacent region under the gate electrode. The adjacent region is adjacent to the active region under the gate electrode. The adjacent region is provided between the distant region and the active region, and has a smaller thickness than the distant region.

### CROSS-REFERENCE TO RELATED APPLICATION

This application claims priority under 35 USC 119 from Japanese Patent Application No. 2021-211455, filed on Dec. 24, 2021, the disclosure of which is incorporated by reference herein.

### BACKGROUND

### Technical Field

The present invention relates to a semiconductor memory device, a method for fabricating the semiconductor memory device, a semiconductor integrated circuit and a semiconductor memory integrated circuit.

### Related Art

Japanese Patent Application Laid-Open (JP-A) No. H07-249696 discloses a mask ROM. In this mask ROM, a number of memory transistors in which ions are implanted for encoding of the ROM is reduced in order to suppress lattice defects that form inside a substrate and to make encoding easier.

Mask ROMs broadly include NAND-type Mask ROMs and NOR-type Mask ROMs. In a NAND-type mask ROM, threshold values of specified transistors are lowered by ion implantation to fabricate depreciation transistors. In a NOR-type mask ROM, threshold values of specified transistors are raised by ion implantation to fabricate enhancement transistors. In the NOR-type mask ROM, selected word lines provide voltage to gate electrodes of memory transistors. A readout circuit detects which of two states (high threshold value or low threshold value) each memory transistor is in.

Programming procedures of these mask ROMs alter current characteristics of the transistors in accordance with implanted dopant densities. However, because heat is applied in fabrication steps subsequent to an ion implantation step, implanted dopants may be relocated by dispersion of the dopants. In a NOR-type mask ROM this dopant relocation occurs in a direction from the interior toward the surface of the substrate, altering the current characteristics of the transistors. This alteration of the characteristics may cause misreading of encoded content of the memory transistors at a readout circuit. This possibility is unavoidable when shifting of the threshold value by an ion implantation process is employed to encode the memory transistors.

### SUMMARY

The present disclosure provides a semiconductor memory device with a structure that may provide any one of plural current characteristics without varying transistor width, and provides a method for fabricating the semiconductor memory device, a semiconductor integrated circuit including a current source circuit and a bias source, and a semiconductor memory integrated circuit including the semiconductor integrated circuit and the semiconductor memory device.

A first aspect of the present disclosure is a semiconductor memory device including: a semiconductor region including a first active region for a first memory transistor and plural depressions for trench isolation; a plurality of insulating regions respectively provided at the depressions of the semiconductor region; a first gate electrode that extends in a first direction from one to another of, among the plurality of insulating regions, a first insulating region and a second insulating region that are next to one another, the first gate electrode passing over the first active region; and a first gate insulation film provided between the first gate electrode and the first active region, wherein: the first active region of the semiconductor region is provided between the first insulating region and the second insulating region; at least one of the first insulating region or the second insulating region includes an adjacent region and a distant region; the adjacent region is adjacent to the first active region under the first gate electrode; the distant region is adjacent to the adjacent region under the first gate electrode; the adjacent region is provided between the distant region and the first active region; a thickness of the adjacent region is smaller than a thickness of the distant region; the semiconductor region includes a first conductive region and a second conductive region provided between the first insulating region and the second insulating region; and the first conductive region, the first active region and the second conductive region are arrayed in a second direction crossing the first direction.

According to the semiconductor memory device according to the first aspect, since the adjacent region under the first gate electrode has a smaller thickness than the thickness of the distant region, the gate insulation film and the gate electrode are provided not just at an upper face of the first active region but also along a side face of the first active region. The gate insulation film and gate electrode over the side face of the first active region may operate as an additional transistor without ion implantation being applied for ROM encoding. Thus, respective structures of transistors with plural current driving capabilities may be provided without varying transistor width.

In a second aspect of the present disclosure, in the first aspect, the semiconductor region may further include a second active region for a second memory transistor that is provided between the first insulating region and the second insulating region; the semiconductor memory device may further include: a second gate electrode that extends in the first direction above the second active region and passes over the second active region, and a second gate insulation film provided between the second gate electrode and the second active region; the semiconductor region may further include a third conductive region provided between the first insulating region and the second insulating region; conductivity types of the first conductive region, the second conductive region and the third conductive region may be different from a conductivity type of the first active region; the second conductive region, the first active region, the first conductive region, the second active region and the third conductive region may be arrayed in this order in the second direction; the second conductive region and the third conductive region may be connected to a reference potential line; and the first conductive region may be shared by the first memory transistor and the second memory transistor and is connected to a metal wiring layer.

According to the semiconductor memory device according to the second aspect, the first memory transistor and the second memory transistor may exhibit three types of current characteristic depending on the presence or absence of the adjacent region(s); specifically, current characteristics according to whether an additional transistor is provided at one side, additional transistors are provided at both sides, or there is no additional transistor.

In a third aspect of the present disclosure, in the first and second aspects, the thickness of the adjacent region of the first insulating region may be smaller than the thickness of the distant region, and the second insulating region under the first gate electrode may be thicker than the adjacent region of the first insulating region.

According to the semiconductor memory device according to the third aspect, the additional transistor is provided at the first insulating region, and the second insulating region has greater thickness than the adjacent region of the first insulating region.

In a fourth aspect of the present disclosure, in the first and second aspects, in each of the first insulating region and the second insulating region, the thickness of the adjacent region may be smaller than the thickness of the distant region.

According to the semiconductor memory device according to the fourth aspect, additional transistors are provided at both the first insulating region and the second insulating region.

In a fifth aspect of the present disclosure, in the first to fourth aspects, the insulating regions may include a third insulating region neighboring the second insulating region; the first insulating region, the second insulating region and the third insulating region may be arrayed in this order in the first direction; the semiconductor region may further include a third active region for a third memory transistor; the first gate electrode may extend in the first direction and passes over the third active region; the semiconductor memory device may further include a third gate insulation film provided between the first gate electrode and the third active region; the third insulating region may include an adjacent region and a distant region; the adjacent region of the third insulating region may be adjacent to the first active region under the first gate electrode, the distant region of the third insulating region may be adjacent to the adjacent region under the first gate electrode, and the adjacent region may be provided between the distant region and the first active region; a thickness of the adjacent region of the third insulating region under the first gate electrode may be smaller than a thickness of the distant region of the third insulating region; and the second insulating region under the first gate electrode may be thicker than the adjacent region of the third insulating region.

According to the semiconductor memory device according to the fifth aspect, the third memory transistor has a structure in which an additional transistor is provided not at the second insulating region but at the third insulating region. According to this structure, a structure in which no adjacent region is provided may be provided between the second memory transistor and the third memory transistor.

In a sixth aspect of the present disclosure, in the fourth and fifth aspects, the insulating regions may include a fourth insulating region neighboring the first insulating region; the semiconductor region may further include a fourth active region for a fourth memory transistor provided between the first insulating region and the fourth insulating region; the first gate electrode may extend in the first direction and passes over the fourth active region; the semiconductor memory device may further include a fourth gate insulation film provided between the first gate electrode and the fourth active region; the first insulating region may include a further adjacent region that is adjacent to the fourth active region under the first gate electrode; the distant region of the first insulating region may be provided under the first gate electrode between the adjacent region and the further adjacent region of the first insulating region; the further adjacent region may be provided between the distant region and the fourth active region; and a thickness of the further adjacent region under the first gate electrode may be smaller than a thickness of the distant region of the first insulating region.

According to the semiconductor memory device according to the sixth aspect, the fourth memory transistor neighboring the first memory transistor shares a word selection line connected to the gate electrode with the first memory transistor. An additional transistor may be provided at the first insulating region at the fourth memory transistor regardless of whether the first memory transistor includes an additional transistor relating to the first insulating region.

In a seventh aspect of the present disclosure, in the first to sixth aspects, the adjacent region may be one of: a structure that traverses the first gate electrode in a direction from one to the other of the first conductive region and the second conductive region, or a structure that extends from one of the first conductive region and the second conductive region and terminates directly under the first gate electrode.

According to the semiconductor memory device according to the seventh aspect, at least a portion of the adjacent region may be provided directly under the first gate electrode. The adjacent region may have either a structure that traverses the first gate electrode in a direction from a source region toward a drain region of the first memory transistor, or a structure that extends from the source region of the first memory transistor and terminates directly under the first gate electrode.

An eighth aspect of the present disclosure is a method for fabricating a semiconductor memory device, including: preparing a substrate product that includes: a semiconductor region including plural depressions for trench isolation, and a plurality of insulating regions respectively provided at the depressions of the semiconductor region, the semiconductor region including an active region provided between, among the insulating regions, a first insulating region and a second insulating region that are next to one another; forming a mask that includes an opening, on a principal surface of the substrate product; removing an insulator of the insulating regions of the substrate product, using the mask; after removing the insulator, forming a gate insulation film on the active region; and after forming the gate insulation film, forming a gate electrode above the insulating regions and the active region, wherein: the opening of the mask is located above at least one of a first boundary between the active region and the first insulating region or a second boundary between the active region and the second insulating region; removing the insulator of the substrate product includes partially removing the insulator at the opening of the mask and partially exposing a side face of the active region; the gate insulation film is provided on the side face; and the gate electrode traverses the active region in a direction from one to another of the first insulating region and the second insulating region and extends over the gate insulation film on the side face.

According to the fabrication method according to the eighth aspect, a portion of the insulating region that is removed using the opening provides a smaller thickness than a thickness of the insulating region away from the opening. Therefore, the gate insulation film and the gate electrode extend not just at the upper face of the active region but also along a side face of the active region, and the side face of the first active region may operate as an additional transistor. Thus, structures of transistors with plural current driving characteristics may be provided without applying ion implantation to the transistors to alter the threshold values.

In a ninth aspect of the present disclosure, in the eighth aspect, the mask may cover the second boundary.

According to the fabrication method according to the ninth aspect, an additional transistor is provided at one side of the active region.

In a tenth aspect of the present disclosure, in the eighth aspect, the opening of the mask may be located above the first boundary and the second boundary.

According to the fabrication method according to the tenth aspect, respective additional transistors are provided at both sides of the active region.

An elevenths aspect of the present disclosure is a semiconductor integrated circuit including a current source circuit and a bias circuit, wherein: the current source circuit includes at least one transistor, the transistor including: a semiconductor region including plural depressions for trench isolation, plural insulating regions respectively provided at the depressions of the semiconductor region, the plural insulating regions including a first insulating region and a second insulating region that neighbor one another, an active region for the transistor that is provided between the first insulating region and the second insulating region, a gate electrode that extends in a first direction from one to another of the first insulating region and the second insulating region, the gate electrode passing over the active region, and a gate insulation film provided between the gate electrode and the active region; at least one of the first insulating region or the second insulating region includes an adjacent region and a distant region; the adjacent region is adjacent to the active region under the gate electrode; the adjacent region is adjacent to the distant region under the gate electrode; the adjacent region is provided between the distant region and the active region under the gate electrode; a thickness of the adjacent region is smaller than a thickness of the distant region; the semiconductor region includes a first conductive region provided between the first insulating region and the second insulating region, and a second conductive region provided between the first insulating region and the second insulating region; the first conductive region, the active region and the second conductive region are arrayed in a second direction crossing the first direction; and the bias source is connected to the gate electrode and provides a voltage to the gate electrode.

According to the semiconductor integrated circuit according to the eleventh aspect, the transistor may present any of plural current characteristics depending on the presence or absence of the adjacent region; specifically, current characteristics for an additional transistor at one side or for additional transistors at both sides.

An twelfth aspect of the present disclosure is a semiconductor integrated memory circuit including: a semiconductor integrated circuit according to the eleventh aspect; a semiconductor memory circuit according to one of the first to the seventh aspect; and a readout circuit structured to read the first memory transistor of the semiconductor memory device, wherein the readout circuit is connected to the semiconductor memory device and is structured to compare a current from the first memory transistor with a current from the current source circuit of the semiconductor integrated circuit.

According to the semiconductor memory integrated circuit according to the twelfth aspect, the readout circuit of the semiconductor memory device may use the semiconductor integrated circuit including the current source circuit to identify a difference in the current characteristic of the first memory transistor.

According to the aspects described above, a semiconductor memory device relating to the present disclosure, a method for fabricating the semiconductor memory device, a semiconductor integrated circuit including a current source circuit and a bias source, and a semiconductor memory integrated circuit including the semiconductor integrated circuit and the semiconductor memory device may provide any one of plural current characteristics without varying transistor width.

### BRIEF DESCRIPTION OF THE DRAWINGS

Exemplary embodiments will be described in detail based on the following figures, wherein:

FIG. 1 is a diagram schematically illustrating a semiconductor memory integrated circuit according to a present exemplary embodiment;

FIG. 2 is a diagram illustrating a portion of a semiconductor memory device according to an exemplary embodiment of the present disclosure;

FIG. 3A is a plan view illustrating a transistor disposed in an area T3 (or area T3R) of FIG. 2;

FIG. 3B is a cross-sectional diagram taken along line IIIb-Mb illustrated in FIG. 3A;

FIG. 3C is a cross-sectional diagram taken along line IIIc-IIIc illustrated in FIG. 3A;

FIG. 4A is a plan view illustrating a transistor disposed in an area T4 of FIG. 2;

FIG. 4B is a cross-sectional diagram taken along line IVb-IVb illustrated in FIG. 4A;

FIG. 4C is a magnified view illustrating a step for an additional transistor;

FIG. 5A is a plan view illustrating a transistor disposed in an area T5 of FIG. 2;

FIG. 5B is a cross-sectional diagram taken along line Vb-Vb illustrated in FIG. 5A;

FIG. 6 is a diagram illustrating saturation current characteristics (IDS1, IDS2 and IDS3) of three types of transistor;

FIG. 7A is a diagram illustrating an arrangement of three types of memory transistor in an array of a semiconductor memory device according to an exemplary embodiment of the present disclosure;

FIG. 7B is a diagram schematically illustrating distributions of current characteristics of the three types of memory transistor, “None”, “Either” and “Both”, in the array of the semiconductor memory device according to the exemplary embodiment of the present disclosure;

FIG. 8 is a circuit diagram illustrating an example of a readout circuit of a semiconductor memory integrated circuit according to the present exemplary embodiment;

FIG. 9 is a circuit diagram illustrating an example of a semiconductor integrated circuit for a current source according to the present exemplary embodiment;

FIG. 10 is a circuit diagram illustrating another example of a semiconductor integrated circuit for a current source according to the present exemplary embodiment;

FIG. 11A, FIG. 11B and FIG. 11C are cross-sectional diagrams illustrating principal steps in a method for fabricating a semiconductor integrated circuit according to an exemplary embodiment of the present disclosure;

FIG. 12A, FIG. 12B and FIG. 12C are cross-sectional diagrams illustrating principal steps in the method for fabricating the semiconductor integrated circuit according to the exemplary embodiment of the present disclosure;

FIG. 13A, FIG. 13B and FIG. 13C are cross-sectional diagrams illustrating principal steps in the method for fabricating the semiconductor integrated circuit according to an alternative exemplary embodiment of the present disclosure;

FIG. 14A, FIG. 14B and FIG. 14C are cross-sectional diagrams illustrating principal steps in the method for fabricating the semiconductor integrated circuit according to the exemplary embodiment of the present disclosure;

FIG. 15 is a plan view illustrating a principal step in the method for fabricating the semiconductor integrated circuit according to the exemplary embodiment of the present disclosure; and

FIG. 16A, FIG. 16B and FIG. 16C are cross-sectional diagrams illustrating principal steps in the method for fabricating the semiconductor integrated circuit according to the exemplary embodiment of the present disclosure.

### DETAILED DESCRIPTION

Below, exemplary embodiments for embodying the present disclosure are described with reference to the attached drawings. In the following descriptions, portions that are the same or similar are assigned reference symbols that are the same or similar, and duplicative descriptions are avoided.

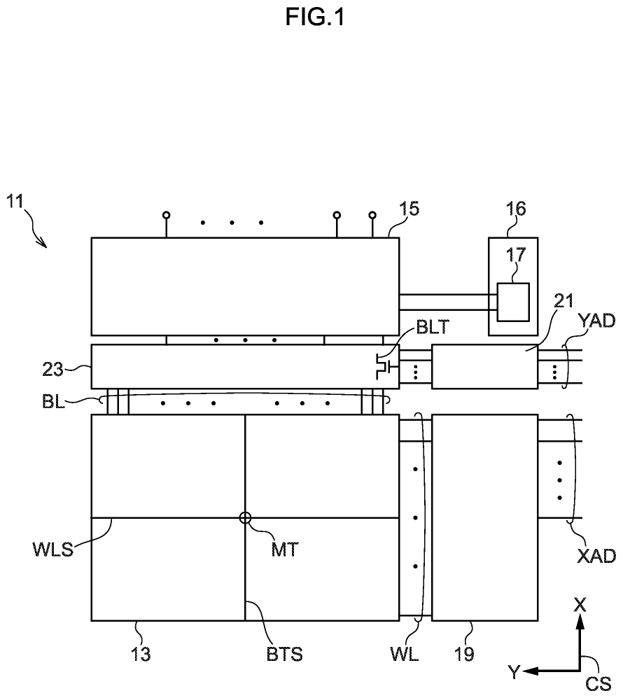

FIG. 1 is a diagram schematically illustrating a semiconductor memory integrated circuit according to a present exemplary embodiment. A semiconductor memory integrated circuit 11 includes a semiconductor memory device 13, a readout circuit 15, a reference circuit 16, a current source circuit 17, a word decoding circuit 19, a bit decoding circuit 21 and a bit selection circuit 23.

The semiconductor memory device 13 includes plural memory transistors. These memory transistors are commonly arranged so as to form one-dimensional or two-dimensional arrays. For example, in a two-dimensional transistor array, plural memory transistors are arranged in direction X of the coordinate system CS indicated in FIG. 1, and respective gate electrodes of the memory transistors are connected to a word line WL to structure a one-dimensional subarray. A plural number of the subarrays are arranged in direction Y of the coordinate system CS indicated in FIG. 1, and corresponding drain electrodes in each subarray are connected to respective bit lines BL to structure the two-dimensional array. The semiconductor memory device 13 may be referred to as being, for example, a NOR-type mask ROM.

In the semiconductor memory device 13, the word decoding circuit 19 is connected to the plural word lines WL. In accordance with a memory address (more specifically, an X address XAD), the word decoding circuit 19 selects one word line WLS from the plural word lines WL. When the word line WLS is selected, all memory transistors connected to that word line WLS are made conductive.

Bit selection transistors BLT in the bit selection circuit 23 are connected to the plural bit lines BL. The bit decoding circuit 21 selects a bit selection transistor BLT in the bit selection circuit 23. As a result, in accordance with a memory address (more specifically, a Y address YAD), one or a plural number of bit lines BTS (for example, eight lines (a byte) or 16 lines (a word)) are selected from the plural bit lines BL. When a bit line BTS is selected, any one of the memory transistors connected to that bit line BTS can be connected to the selected word line WL. A transistor MT selected by this technique is located at the intersection of the single selected word line WLS and a selected bit line BTS.

All of the bit lines BL are connected to one or a plural number of the readout circuit 15 via the bit selection transistors BLT in the bit selection circuit 23. Each readout circuit 15 is structured to read the memory transistors of the semiconductor memory device 13. More specifically, the readout circuit 15 senses memory contents of selected memory transistors and outputs sensing results. In the present exemplary embodiment, the readout circuit 15 is connected to the current source circuit 17 in the reference circuit 16 of the semiconductor integrated circuit. The readout circuit 15 is structured to use the current source circuit 17 to sense the memory content of a selected memory transistor, comparing a current from the memory transistor with a current from the current source circuit 17 to identify a difference in the current characteristic of the memory transistor. However, the semiconductor memory integrated circuit 11 according to the present disclosure is not limited thus.

As can be understood from the descriptions below, the selected memory transistors MT exhibit three types of current characteristic in accordance with structures of the memory transistors MT.

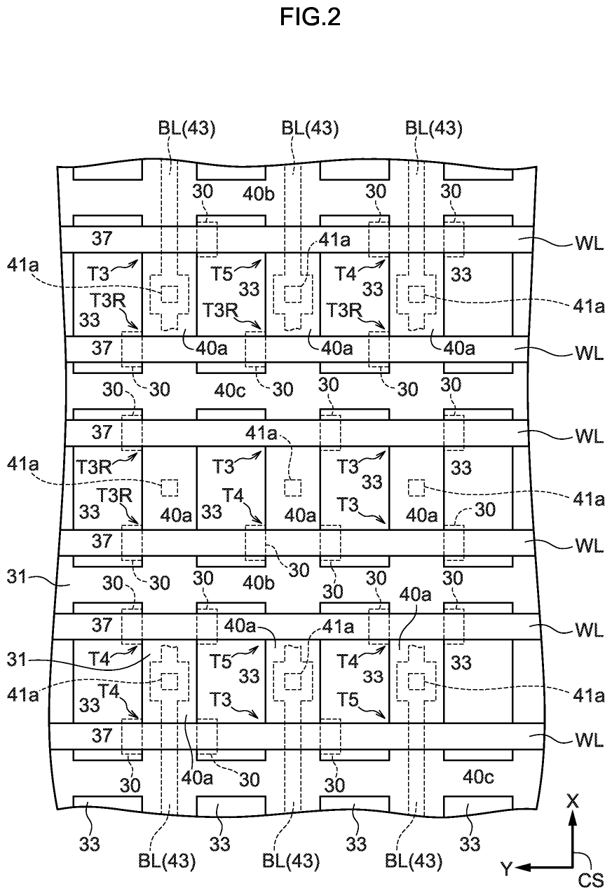

FIG. 2 is a plan view illustrating a portion of the semiconductor memory device 13. Referring to FIG. 2, the coordinate system CS of FIG. 1 is illustrated to show the orientation of the semiconductor memory device 13. In FIG. 2, gate electrodes 37 and element-isolating insulating regions 33 are illustrated by solid lines; contact plugs 41a (contact holes) to a conductive semiconductor region 31, recess portions 30 for additional transistors, and metal layers for the bit lines BL are illustrated by broken lines. The metal layers are only partially illustrated, to avoid complication of the drawing. In the transistor array illustrated in FIG. 2, specifically, structures T3 (and T3R), structures T4 and structures T5 exhibit the three types of current characteristic. Transistors of any one type of structure of the three types are disposed at individual intersections of the bit lines BL and word lines WL.

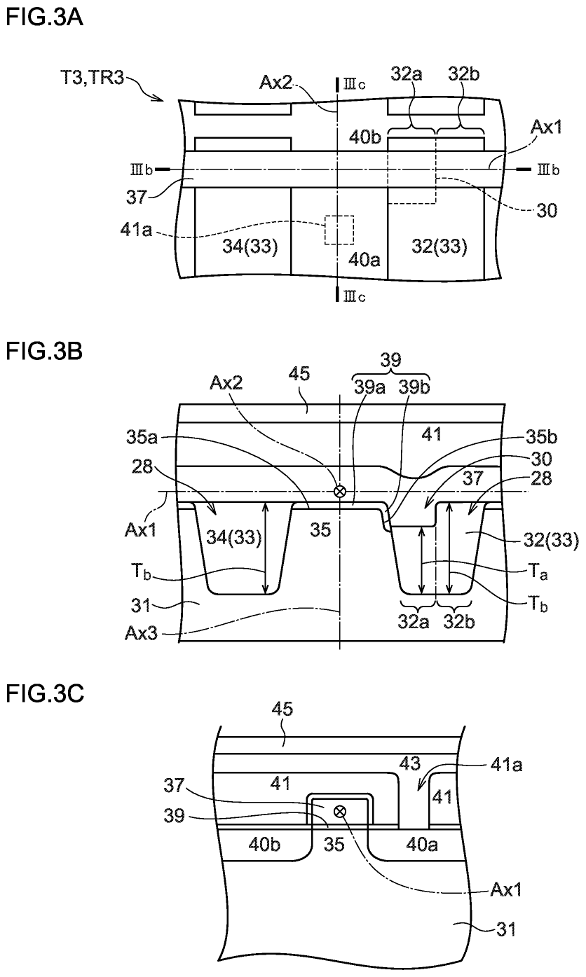

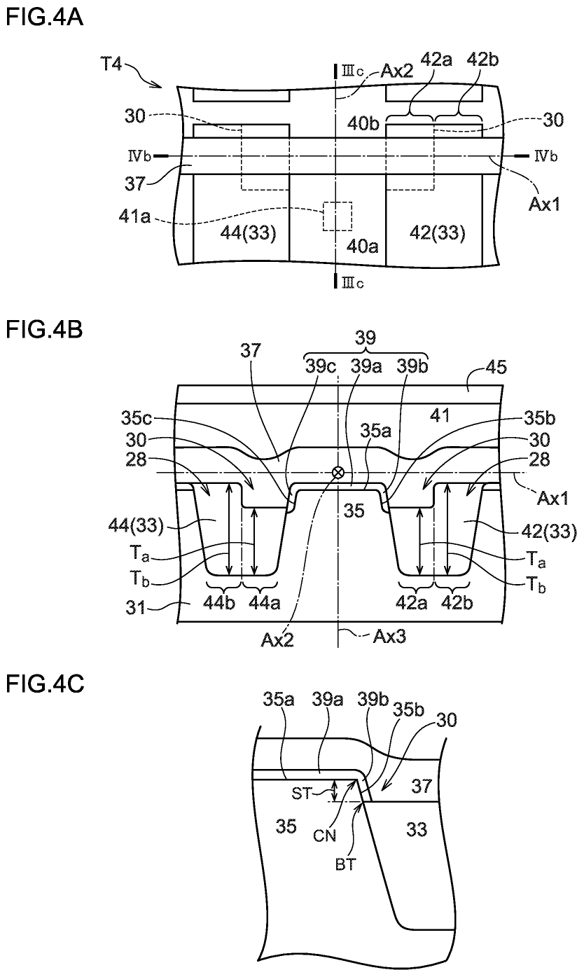

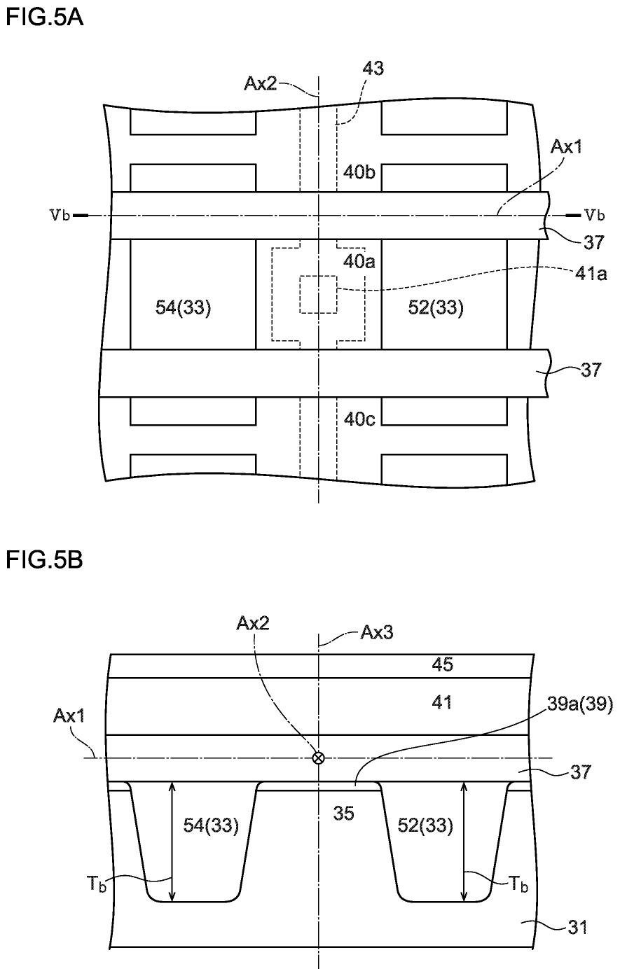

FIG. 3A is a plan view illustrating a transistor located in one of the structures T3 of FIG. 2 (the structure T3R is a left-and-right inversion of the structure T3). FIG. 3B is a cross-sectional diagram taken along line IIIb-Mb illustrated in FIG. 3A. FIG. 3C is a cross-sectional diagram taken along line IIIc-IIIc illustrated in FIG. 3A. FIG. 4A is a plan view illustrating a transistor located in one of the structures T4 of FIG. 2. FIG. 4B is a cross-sectional diagram taken along line IVb-IVb illustrated in FIG. 4A. FIG. 5A is a plan view illustrating a transistor located in one of the structures T5 of FIG. 2. FIG. 5B is a cross-sectional diagram taken along line Vb-Vb illustrated in FIG. 5A.

Referring to FIG. 2, FIG. 3A to FIG. 3C, FIG. 4A, FIG. 4B, FIG. 5A and FIG. 5B, the semiconductor memory device 13 includes the semiconductor region 31 (for example, a silicon region), a plural number of the insulating regions 33, a plural number of the gate electrodes 37 for memory transistors, and gate insulation films 39 for the memory transistors. The semiconductor region 31 includes a plural number of active regions 35 for the memory transistors. The semiconductor region 31 may include a silicon-based conductor, for example, silicon, silicon—germanium or silicon carbide, and is provided by, for example, a semiconductor board or semiconductor wafer. The insulating regions 33 may include a silicon-based inorganic insulator, for example, silicon oxide, silicon nitride or silicon oxynitride. The gate insulation films 39 may include a high permittivity insulating film, for example, including silicon oxide or silicon nitride.

As illustrated in FIG. 3A to FIG. 3C, FIG. 4A, FIG. 4B, FIG. 5A and FIG. 5B, the semiconductor region 31 includes the active regions 35 for the memory transistors and a plural number of depressions 28 for shallow trench isolation. The plural insulating regions 33 are respectively provided at the depressions 28 of the semiconductor region 31. Each active region 35 is provided between two of the insulating regions 33 that neighbor one another. Each gate electrode 37 extends in a first direction Ax1 from one to another of the pair of neighboring insulating regions 33, and the gate electrode 37 passes over the active region 35. Each gate insulation film 39 is provided between the corresponding gate electrode 37 and active region 35.

The semiconductor region 31 includes first conductive regions 40a and second conductive regions 40b. The first conductive regions 40a and second conductive regions 40b are provided between pairs of neighboring insulating regions 33. Each of the first conductive regions 40a and second conductive regions 40b has a different conductivity type (for example, n-type) from the conductivity type of the active regions 35 (for example, p-type). The first conductive regions 40a and second conductive regions 40b are arrayed in a second direction Ax2 that crosses (for example, is orthogonal to) the first direction Ax1. Each active region 35 is between the corresponding first conductive region 40a and second conductive region 40b and is adjacent to the first conductive region 40a and second conductive region 40b.

Referring to FIG. 3C, the semiconductor memory device 13 includes an interlayer insulating film 41 provided on the gate electrodes 37 and insulating regions 33, and a metal wiring layer 43 extending over the interlayer insulating film 41. The metal wiring layer 43 is connected to the second conductive regions 40b via the contact plugs 41a (contact holes) in the interlayer insulating film 41. The interlayer insulating film 41 and metal wiring layer 43 are covered by a protective insulating film 45. The interlayer insulating film 41 may include a silicon-based inorganic insulator (for example, silicon oxide, silicon nitride or silicon oxynitride), and the protective insulating film 45 may include a silicon-based inorganic insulator.

Referring to FIG. 3A to FIG. 3C, each of some of the active regions 35 is provided between, of the insulating regions 33, a first insulating region 32 and a second insulating region 34 that neighbor one another. The first conductive region 40a and second conductive region 40b of the semiconductor region 31 are provided between the first insulating region 32 and the second insulating region 34. One of the first insulating region 32 and the second insulating region 34 (in the present exemplary embodiment, the first insulating region 32) includes an adjacent region 32a and a distant region 32b. In the first insulating region 32, the adjacent region 32a is adjacent to the active region 35 under the gate electrode 37, and the distant region 32b is adjacent to the adjacent region 32a under the gate electrode 37. The adjacent region 32a is provided between the distant region 32b and the active region 35. A portion of the adjacent region 32a has a thickness Ta that is smaller than a thickness Tb of the distant region 32b. The portion of the adjacent region 32a is recessed to the far side of FIG. 3B relative to the distant region 32b and the active region 35, forming the recess portion 30. A thickness of the second insulating region 34 under the gate electrode 37 of the corresponding transistor is greater across a bottom face of the gate electrode 37 than the thickness Ta of the adjacent region 32a, and is substantially the same as the thickness Tb of the distant region 32b.

Referring to FIG. 3B, the active region 35 includes an upper face 35a and a first side face 35b. The upper face 35a extends along a gate insulation film 39a. The side face 35b extends directly under the gate electrode 37 in a third direction Ax3 that crosses the first direction Ax1 and the second direction Ax2. The gate insulation film 39 includes both the gate insulation film 39a on the upper face 35a and a gate insulation film 39b provided on the first side face 35b.

According to this semiconductor memory device 13, the adjacent region 32a under the gate electrode 37 has a thickness smaller than the thickness Tb of the distant region 32b. Therefore, the gate insulation film 39 and the gate electrode 37 are provided along the side face 35b of the active region 35 as well as along the upper face 35a of the active region 35. Because the gate electrode 37 is provided on the gate insulation film 39a on the upper face 35a of the active region 35, the upper face 35a of the active region 35 may operate as a channel for a main transistor. Meanwhile, the gate insulation film 39b and gate electrode 37 on the side face 35b of the active region 35 allow the side face 35b of the active region 35 to operate as a channel for an additional transistor. This structure may provide current driving capabilities of the main transistor and the single additional transistor without varying width of the transistor.

According to this semiconductor memory device 13, an additional transistor is provided at the first insulating region 32 but no additional transistor is provided at the second insulating region 34. Because the second insulating region 34 is provided with the thickness Tb that is greater than that of the adjacent region 32a of the first insulating region 32, the second insulating region 34 directly under the gate electrode 37 extends along the active region 35 and the gate electrode, and the second insulating region 34 may isolate elements.

According to this semiconductor memory device 13, a gap-fill of an insulator is provided for trench isolation in a lower portion of each depression 28 of the semiconductor region 31, and the conductor of the gate electrode 37 is provided on the first side face 35b in association with an upper portion of the depression 28 of the semiconductor region 31. This conductor is isolated from the active region 35 by the gate insulation film 39a and the gate insulation film 39b.

Referring to FIG. 4A and FIG. 4B, each of some of the active regions 35 is provided between, of the insulating regions 33, a third insulating region 42 and a fourth insulating region 44 that neighbor one another. The corresponding first conductive region 40a and second conductive region 40b of the semiconductor region 31 are provided between the third insulating region 42 and the fourth insulating region 44.

The third insulating region 42 includes an adjacent region 42a and a distant region 42b. The adjacent region 42a is adjacent to the active region 35 under the gate electrode 37, and the distant region 42b is adjacent to the adjacent region 42a under the gate electrode 37. The adjacent region 42a is provided between the distant region 42b and the active region 35. A portion of the adjacent region 42a has a thickness Ta that is smaller than a thickness Tb of the distant region 42b. A portion of the adjacent region 42a is recessed to the far side of FIG. 4B relative to the distant region 42b and the active region 35, forming the recess portion 30.

The fourth insulating region 44 includes an adjacent region 44a and a distant region 44b. The adjacent region 44a is adjacent to the active region 35 under the gate electrode 37, and the distant region 44b is adjacent to the adjacent region 44a under the gate electrode 37. The adjacent region 44a is provided between the distant region 44b and the active region 35. A portion of the adjacent region 44a has a thickness Ta that is smaller than a thickness Tb of the distant region 44b. A portion of the adjacent region 44a is recessed to the far side of FIG. 4B relative to the distant region 44b and the active region 35, forming another of the recess portion 30.

According to this semiconductor memory device 13, the adjacent regions 42a and 44a under the gate electrode 37 have thicknesses Ta smaller than the thicknesses Tb of the distant regions 42b and 44b. Therefore, the gate insulation film 39 and the gate electrode 37 are provided along two side faces 35b and 35c of the active region 35 as well as along the upper face 35a of the active region 35. Because the gate electrode 37 is provided on the gate insulation film 39a on the upper face 35a of the active region 35, the upper face 35a of the active region 35 operates as a channel for a main transistor. Meanwhile, the gate electrode 37 extends along the gate insulation films 39b and 39c on the side faces 35b and 35c of the active region 35. As a result, the side faces 35b and 35c of the active region 35 may operate as respective channels for additional transistors.

According to this semiconductor memory device 13, an additional transistor is provided at the third insulating region 42 and an additional transistor is also provided at the fourth insulating region 44. This structure may provide current driving capabilities of the main transistor and the two additional transistors without varying width of the transistor. Because the distant regions 42b and 44b of the third insulating region 42 and fourth insulating region 44 are provided with the large thicknesses Tb, the distant regions 42b and 44b directly under the gate electrode 37 extend along the gate electrode 37, and the distant regions 42b and 44b may isolate elements.

Referring to FIG. 4B, in addition to the upper face 35a, the active region 35 includes the first side face 35b and the second side face 35c. The first side face 35b and second side face 35c extend directly under the gate electrode 37 in the third direction Ax3. In addition to the gate insulation film 39a on the upper face 35a, the gate insulation film 39 includes the gate insulation film 39b provided on the first side face 35b and the gate insulation film 39c provided on the second side face 35c.

According to this semiconductor memory device 13, a gap-fill of the insulator is provided for trench isolation under the lower portion of each depression 28 of the semiconductor region 31, and the conductor for the gate electrode 37 is provided on the first side face 35b and second side face 35c at upper portions of the depressions 28 of the semiconductor region 31. This conductor is isolated from the active region 35 by the gate insulation film 39a, the gate insulation film 39b and the gate insulation film 39c.

Referring to FIG. 3A and FIG. 4A, the adjacent regions (32a, 42a and 44a) of the insulating regions 33 may each have a structure that traverses the gate electrode 37 in a direction from one to the other of the first conductive region 40a and the second conductive region 40b. With this structure, when the gate electrode 37 is selected, inversion layers are formed at the boundaries between the side faces 35b and 35c of the active region 35 and the gate insulation films (39b and 39c). These inversion layers are consistently formed in vicinities of the source region of the active region 35, whether the memory transistor is operated in the saturation region or the non-saturation region of the current-voltage characteristic.

When possible, the adjacent regions (32a, 42a and 44a) of the insulating regions 33 may each have a structure that extends from the one of the first conductive region 40a and second conductive region 40b and terminates directly under the gate electrode 37 or a structure that terminates short of reaching the drain region. According to this semiconductor memory device 13, at least portions of the adjacent regions (32a, 42a and 44a) as described above may be provided directly under the gate electrodes 37.

For example, the adjacent regions (32a, 42a and 44a) may each extend from the source region of the memory transistor and terminate before reaching the drain electrode. This structure allows the additional transistors to operate excellently.

FIG. 4C is a magnified diagram illustrating a step for an additional transistor. The size of the step ST may be, for example, between 10 and 100 nm. Near a boundary between the gate insulation film 39b and the gate insulation film 39a (near a corner portion CN), the gate insulation film 39b on the side face 35b of the active region 35 is thinner than the gate insulation film 39a. When the gate insulation film 39b is partially thinned, the current characteristic of the additional transistor is altered. The p-type dopant density of the active region 35 is lower at the depth of the bottom BT of the recess portion 30. When the dopant density is lower, the threshold voltage of the additional transistor is lower and the current characteristic is altered. Because the gate electrode 37 is formed so as to cover the corner portion CN, an electric field from the gate electrode concentrates at the corner portion CN, the threshold voltage of the additional transistor is lower, and the current characteristic is altered. These three effects occur at the corner portion CN, lowering the threshold voltage of the transistor that includes the recess portion 30 and raising the saturation current.

Referring to FIG. 5A and FIG. 5B, two areas T5 for memory transistors are illustrated. The active region 35 for each area T5 is provided between, of the insulating regions 33, a fifth insulating region 52 and a sixth insulating region 54 that neighbor one another. The first conductive region 40a, the second conductive region 40b and a third conductive region 40c of the semiconductor region 31 are provided between the fifth insulating region 52 and the sixth insulating region 54.

Adjacent regions similar to the adjacent regions 42a and 44a of the third insulating regions 42 and fourth insulating regions 44 are not provided at the fifth insulating region 52 and the sixth insulating region 54. The fifth insulating region 52 and sixth insulating region 54 are provided with greater thicknesses than the adjacent regions 42a and 44a directly under the gate electrodes 37, for example, with large thicknesses Tb the same as the distant regions 42b and 44b of the third insulating regions 42 and fourth insulating regions 44.

Similarly to the first conductive region 40a and second conductive region 40b, the third conductive region 40c has a different conductivity type from the conductivity type of the active regions 35. The first conductive region 40a, second conductive region 40b and third conductive region 40c have greater electrical conductivity than an electrical conductivity of the active regions 35.

The second conductive region 40b, the active region 35 for one of the memory transistors, the first conductive region 40a, the active region 35 for the other of the memory transistors, and the third conductive region 40c are arrayed in this order in the second direction Ax2. In the present exemplary embodiment, the second conductive region 40b and third conductive region 40c are connected to a reference potential line (for example, a ground line). The first conductive region 40a is shared by the two memory transistors and is connected to the metal wiring layer 43 (a bit line) via one of the contact plugs 41a (a contact hole).

According to the semiconductor memory device 13 as illustrated in FIG. 3A to FIG. 3C, FIG. 4A, FIG. 4B, FIG. 5A and FIG. 5B, the memory transistors may exhibit three types of current characteristic depending on the presence or absence of the adjacent regions (32a, 42a and 44a) in the insulating regions 33 that neighbor one another with a prescribed width of the active regions 35, specifically, current characteristics according to the presence of an additional transistor at one side, additional transistors at both sides, or no additional transistor.

Hitherto, in a memory array of a ROM, adjacent transistors with no additional transistors have been disposed so as to share a drain region. Referring to FIG. 5A and FIG. 5B, a combination of adjacent transistors that share a drain region is illustrated. The combination in FIG. 5A and FIG. 5B is referred to as D (T5, T5). This notation is employed for other combinations as arrangements indicating D (upper side transistor, lower side transistor). In this Specification, the upper side transistor and lower side transistor in “D (upper side transistor, lower side transistor)” may be switched. Referring back to FIG. 2, various arrangements of the three kinds of memory transistors are possible in a two-dimensional memory array.

Combinations of adjacent transistors that share a drain source are illustrated below.
D (T3, T3)
D (T3, T3R)
D (T3, T4)
D (T3, T5)
D (T3R, T3R)
D (T3R, T4)
D (T3R, T5)
D (T4, T4)
D (T4, T5)

Hitherto, in a memory array of a ROM, adjacent transistors with no additional transistors have been disposed so as to share a word line. This combination is referred to in the notation mentioned above as W (T5, T5). This notation is employed for other combinations as arrangements indicating W (left side transistor, right side transistor). In this Specification, the left side transistor and right side transistor in “W (left side transistor, right side transistor)” may be switched.

Combinations of adjacent transistors that share a word line are illustrated below.
W (T3, T3)
W (T3, T4)
W (T3, T5)
W (T3R, T3)
W (T3R, T3R)
W (T3R, T4)
W (T3R, T5)
W (T4, T3)
W (T4, T3R)
W (T4, T5)
W (T5, T3)
W (T5, T3R)
W (T5, T4)
When required, the combinations below may be employed.
W (T3, T3R)
W (T4, T4)

In these structures, in the insulating region 33 located between the active regions 35 of the two transistors, an adjacent region, a distant region and a further adjacent region are arranged in this order directly under the gate electrode 37.

In these combinations, additional transistors belonging to the two adjacent transistors sharing the gate electrode 37 are provided at the insulating region 33 between the two adjacent transistors. The insulating region 33 has an element-isolating structure in which an adjacent region (32a, 42a or 44a), a distant region (32b, 42b or 44b) and an adjacent region (32a, 42a or 44a) are arranged directly under the gate electrode 37 in this order from one to the other of the two adjacent transistors.

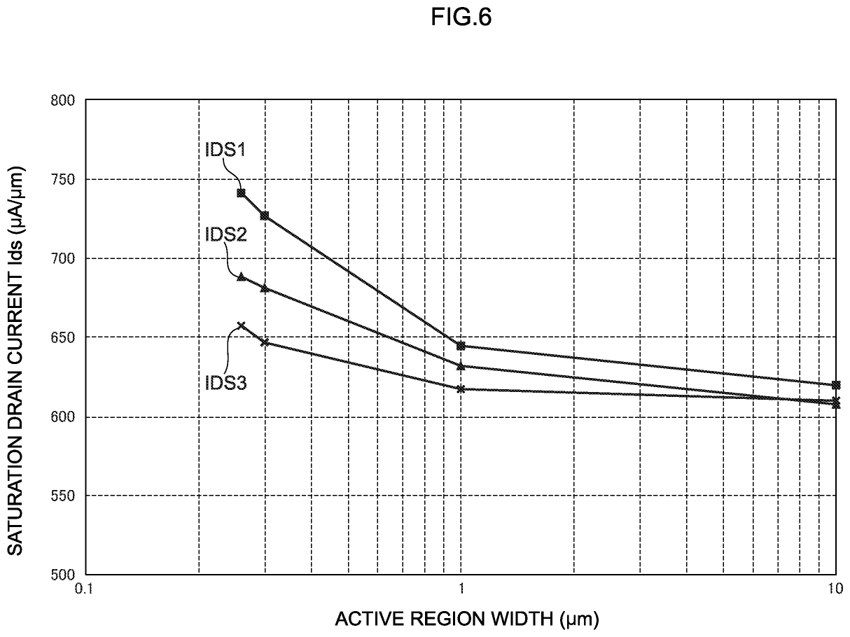

FIG. 6 is a diagram illustrating the three types of current characteristic (IDS1, IDS2 and IDS3) of the transistors. In the graph of current characteristics, the vertical axis represents drain saturation currents (standard values) per unit (1 μm) of width of the active region, and the horizontal axis represents widths of the active region on a logarithmic scale.

Each of the current characteristics (IDS1 to IDS3) represents a current characteristic according to the structure of additional transistors. The current characteristic IDS1 represents a current characteristic according to the structure with additional transistors at both sides, the current characteristic IDS2 represents a current characteristic according to the structure with an additional transistor at one side, and the current characteristic IDS3 represents a current characteristic according to the structure with no additional transistors. At the 0.3 μm point of the horizontal axis, the current value (standard value) of the current characteristic IDS3 is about 650 μA/μm, the current value (standard value) of the current characteristic IDS2 is about 680 μA/μm, and the current value (standard value) of the current characteristic IDS1 is about 720 μA/μm. Thus, a current difference (difference in standard values) between the current characteristic IDS1 and the current characteristic IDS2 is 40 μA/μm and a current difference (difference in standard values) between the current characteristic IDS2 and the current characteristic IDS3 is 30 μA/μm.

For transistors with an active region width of 0.3 μm, the difference in drain saturation current with additional transistors at both sides is about 10 μm, and the current difference with an additional transistor at one side is about 10 μm.

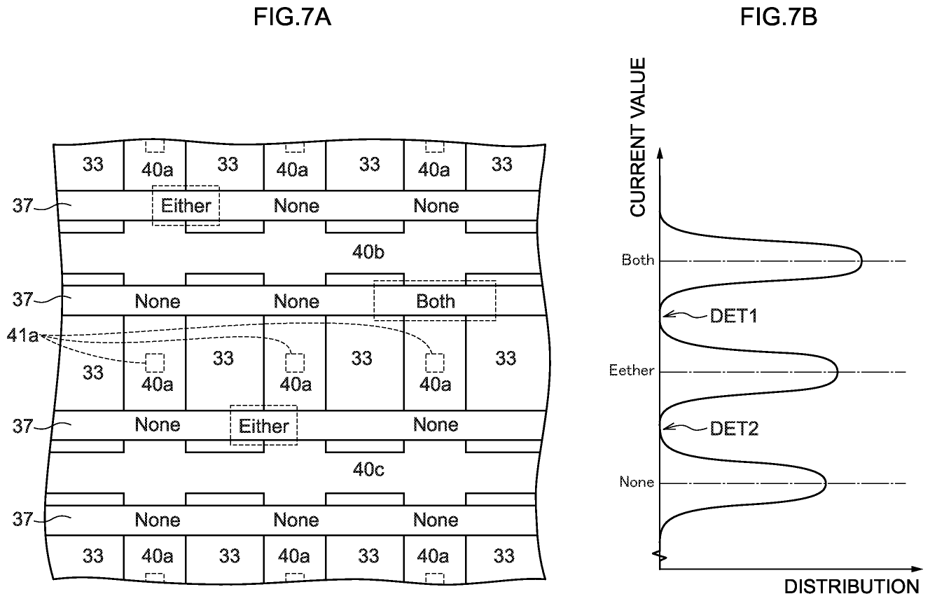

FIG. 7A shows an exemplary arrangement of the three types of memory transistor in an array of the semiconductor memory device 13. The labels “None”, “Either” and “Both” marked on the gate electrodes 37 indicate whether or not the memory transistors include additional transistors. “None” indicates a transistor that has no additional transistor, “Either” indicates a transistor that has an additional transistor at one side, and “Both” indicates a transistor that has additional transistors at both sides.

FIG. 7B schematically shows distributions of the characteristics of the three types of memory transistor, None, Either and Both, in an array of the semiconductor memory device 13. In FIG. 7B, the vertical axis represents typical currents when memory transistors with active region widths of 0.3 μm are conductive, and the horizontal axis represents frequencies of occurrence of the individual transistors.

An example of a method of reading (evaluating) memory contents of the memory transistors of the semiconductor memory device 13 is described. The readout circuit 15 illustrated in FIG. 1 is used to read memory contents at the three values of the memory transistors. In FIG. 7B, a certain sensing level (for example, DET1) may be used to distinguish the None memory transistors from the Either memory transistors, and a certain sensing level (for example, DET2) may be used to distinguish the Either memory transistors from the Both memory transistors.

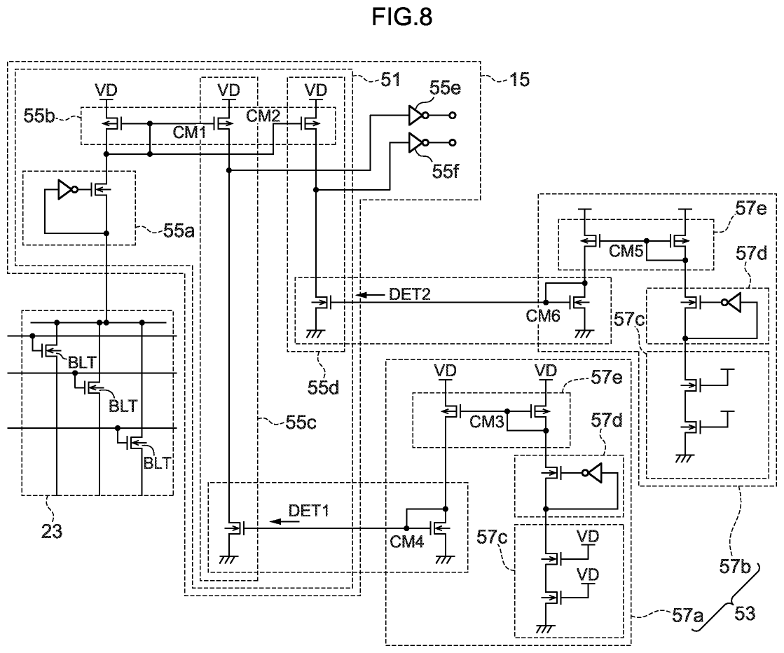

FIG. 8 is a circuit illustrating an example of the readout circuit 15 of the semiconductor memory integrated circuit according to the present exemplary embodiment. The readout circuit 15 includes a sensing circuit 51 and one or a plural number of reference circuits 53. The sensing circuit 51 is connected to the bit lines BL of the semiconductor memory device 13 via bit selection transistors BLT in the bit selection circuit 23. The sensing circuit 51 is connected to each reference circuit 53. The reference circuits 53 generate the two reference levels (DET1 and DET2) for evaluating whether the current characteristics of selected memory transistors are None, Either or Both. The reference circuits 53 provide signals expressing the reference levels (DET1 or DET2) to the sensing circuit 51.

The sensing circuit 51 includes a feedback circuit 55a, a load circuit 55b, and comparison circuits 55c and 55d. The feedback circuit 55a sets the potential level of a bit line BL, senses changes in the potential level, and controls the bit line BL. The load circuit 55b receives current from a selected memory transistor MT. The comparison circuits 55c and 55d constitute current mirror circuits with the load circuit 55b and compare mirror currents received from a current mirror circuit CM1 with reference currents from the reference circuits 53 (the reference levels DET1 and DET2). The readout circuit 15 further includes logic gates 55e and 55f. The logic gates 55e and 55f are connected to outputs of, respectively, the comparison circuits 55c and 55d of the sensing circuit 51. The logic gates 55e and 55f receive signals from the outputs of, respectively, the comparison circuits 55c and 55d and convert sensing results of the sensing circuit 51 to digital signal logic levels. The logic gates 55e and 55f may be, for example, CMOS inverters.

More specifically, the feedback circuit 55a senses changes in the potential level of a bit line and connects the bit line BL to the load circuit 55b. The load circuit 55b receives current from a selected memory transistor (“MT” in the memory array in FIG. 1). The comparison circuit 55c constitutes the current mirror circuit CM1 with the load circuit 55b, and compares a mirror current received via the current mirror circuit CM1 with a reference current (the reference level DET1) from the reference circuits 53. The comparison circuit 55d constitutes a current mirror circuit CM2 with the load circuit 55b, and compares a mirror current received via the current mirror circuit CM2 with a reference current (the reference level DET2) from the reference circuits 53.

The semiconductor memory integrated circuit 11 according to the present exemplary embodiment includes a DET1 reference circuit 57a and a DET2 reference circuit 57b that generate, respectively, the two reference levels (DET1 and DET2). Each of the DET1 reference circuit 57a and the DET2 reference circuit 57b includes a current source circuit 57c and, equivalent to the feedback circuit 55a and current mirror circuit CM1 of the sensing circuit 51, a feedback circuit 57d and a current mirror circuit 57e.

In the DET1 reference circuit 57a, the current source circuit 57c is specified so as to generate the reference current illustrated in FIG. 7B (reference level DET1). The reference current from the current source circuit 57c is supplied to the current mirror circuit 57e (CM3) via the feedback circuit 57d. The DET1 reference circuit 57a constitutes a current mirror circuit CM4 with a transistor in the comparison circuit 55c, and mirrors a relevant current with the reference current (reference level DET1) at the comparison circuit 55c for evaluation in the comparison circuit 55c. The comparison circuit 55c compares this mirror current with a mirror current from a memory transistor.

Similarly in the DET2 reference circuit 57b, the current source circuit 57c is specified so as to generate the reference current illustrated in FIG. 7B (reference level DET2). The reference current from the current source circuit 57c is supplied to the current mirror circuit 57e (CM5) via the feedback circuit 57d. The DET2 reference circuit 57b constitutes a current mirror circuit CM6 with a transistor in the comparison circuit 55d, and mirrors a relevant current with the reference current (reference level DET2) at the comparison circuit 55d for evaluation in the comparison circuit 55d. The comparison circuit 55d compares this mirror current with a mirror current from a memory transistor.

The readout circuit 15 provides readout results of the memory transistors as illustrated below.

| | Output value of | Output value of |
|---|---|---|
| Type of memory transistor | the logic gate 55e | the logic gate 55f |
| Both | High level | High level |
| Either | High level | Low level |
| None | Low level | Low level |

With an active region width of 0.35 μm or less, the saturation current of the None-type transistors that have no additional transistors is the lowest.

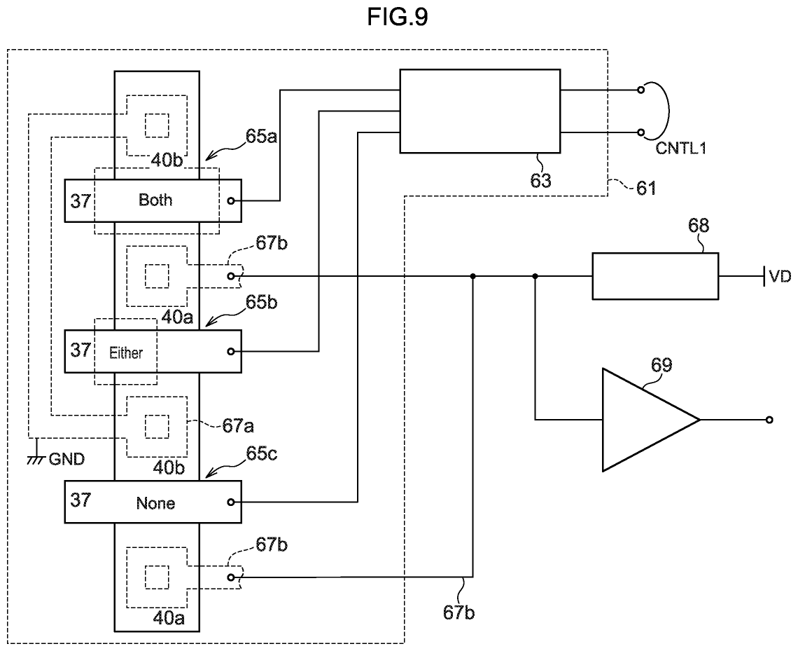

FIG. 9 shows an example of a circuit diagram of a semiconductor integrated circuit for a current source according to the present exemplary embodiment. A current source circuit 61 may be used for the current source circuit 57c. The current source circuit 61 includes one or both of a Both-type transistor and an Either-type transistor and, as necessary, may further include one or a plural number of None-type transistors. When the current source circuit 61 includes the Both-type transistor, one or more of the Both-type transistor may be provided in the current source circuit 61. When the current source circuit 61 includes the Either-type transistor, one or more of the Either-type transistor may be provided in the current source circuit 61.

Referring to FIG. 9, more specifically, the current source circuit 61 includes one Both-type current source transistor 65a, one Either-type current source transistor 65b and one None-type current source transistor 65c.

In the current source circuit 61, drain regions or source regions of the current source transistors (65a, 65b, 65c) that are adjacent to one another are shared by the transistors. The source regions of the current source transistors (65a, 65b, 65c) are connected to a ground line via, for example, a metal wiring layer 67a, and the drain regions of the current source transistors (65a, 65b, 65c) are connected to a metal wiring layer 67b.

The current source circuit 61 includes a switch group 63 with a plural number of switches. The switch group 63 generates signals to select one or a plural number of the current source transistor 65a, the current source transistor 65b and the current source transistor 65c, and the current source circuit 61 generates current from the current source transistors (65a, 65b, 65c). More specifically, the switches of the switch group 63 are connected to the respective gate electrodes of the current source transistors (65a, 65b, 65c), and the switches of the switch group 63 regulate which current source transistors among the current source transistors (65a, 65b, 65c) are made conductive and which of the current source transistors (65a, 65b, 65c) are made non-conductive. The individual switches in the switch group 63 may be solid-state switches that use metal wiring formed in a fabrication process, or may be movable selection switches that respond to external control signals CNTL1 to the switch group 63. These switches may be constituted by transistors.

In the present exemplary embodiment, the metal wiring layer 67b is connected to a power supply line VD via a load circuit 68 outside the current source circuit 61. The load circuit 68 is operated so as to generate a voltage value in accordance with current flowing in the current source circuit 61. This voltage value is provided to an amplifier 69. The amplifier 69 may be, for example, an arithmetic amplifier. The arithmetic amplifier may be connected so as to structure, for example, a voltage buffer circuit (a voltage follower).

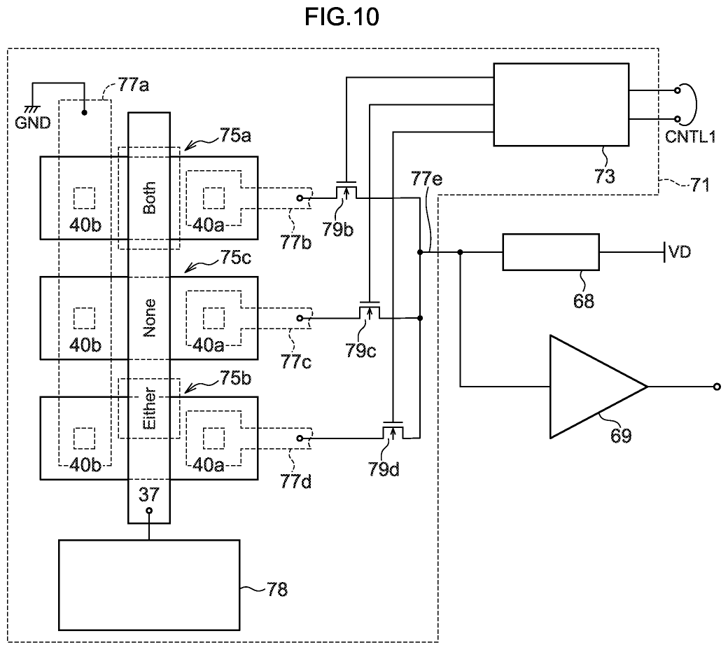

FIG. 10 shows an alternative example of a circuit diagram of the semiconductor integrated circuit for a current source according to the present exemplary embodiment. A current source circuit 71 may be used for the current source circuit 57c. The current source circuit 71 includes one or both of a Both-type transistor and an Either-type transistor and, as necessary, may further include one or a plural number of None-type transistors. When the current source circuit 71 includes the Both-type transistor, one or more of the Both-type transistor may be provided in the current source circuit 71. When the current source circuit 71 includes the Either-type transistor, one or more of the Either-type transistor may be provided in the current source circuit 71.

Referring to FIG. 10, this exemplary circuit includes one Both-type current source transistor 75a, an Either-type current source transistor 75b, and one None-type current source transistor 75c.

In the current source circuit 71, gate electrodes of the current source transistors (75a, 75b, 75c) are shared by the transistors. The source regions of the current source transistors (75a, 75b, 75c) are connected to a ground line via, for example, a metal wiring layer 77a, and the drain regions of the current source transistors (75a, 75b, 75c) are connected to a shared metal wiring layer 77e via respective metal wiring layers 77b, 77c and 77d and selectors 79b, 79c and 79d. The gate electrodes 37 of the current source transistors (75a, 75b, 75c) are connected to a bias source 78. The bias source 78 applies a suitable voltage to the gate electrodes 37 of the current source transistors (75a, 75b, 75c) and, as necessary, may control the current source transistors (75a, 75b, 75c) to be conductive or non-conductive. Each of the selectors 79b, 79c and 79d may be, for example, a transistor. The current source circuit 71 includes a switch group 73 with a plural number of switches for selecting the selectors 79b, 79c and 79d. The switch group 73 provides signals to the current source transistor 75a, current source transistor 75b and current source transistor 75c to select one or more of the current source transistors (75a, 75b, 75c). More specifically, switches of the switch group 73 are connected to the gates of transistors of the selectors 79b, 79c and 79d that are connected to, respectively, the current source transistors 75a, 75c and 75b.

Via the selectors 79b, 79c and 79d, the switches of the switch group 73 regulate which of the current source transistors (75a, 75b, 75c) are selected and which of the current source transistors (75a, 75b, 75c) are made non-conductive. The individual switches in the switch group 73 may be solid-state switches that use metal wiring formed in a fabrication process, and may be selectable in response to external control signals CNTL1 to the switch group 73.

In the present exemplary embodiment, the metal wiring layer 77e is connected to a power supply line VD via the load circuit 68 outside the current source circuit 71. The load circuit 68 is operated so as to generate a voltage value in accordance with current flowing in the current source circuit 71. This voltage value is provided to an amplifier 69.

The current source circuits 61 and 71 illustrated in FIG. 9 and FIG. 10 may be used as current sources and voltage sources for analog circuits. These analog circuits may include, for example, analog-digital converters and digital-analog converters. The readout circuit 15 of the semiconductor memory integrated circuit 11 may employ the current source circuit 61 or 71.

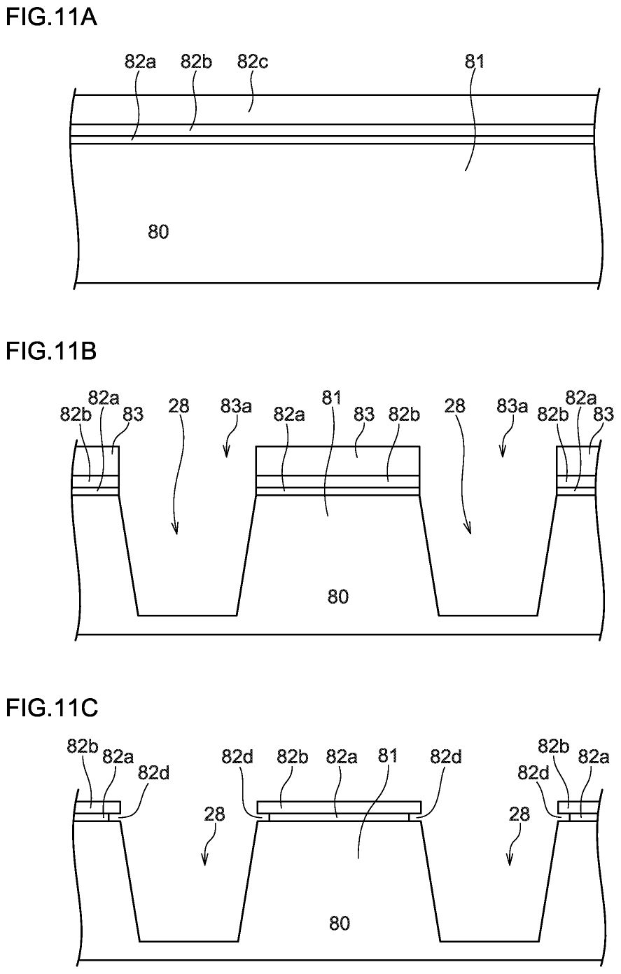

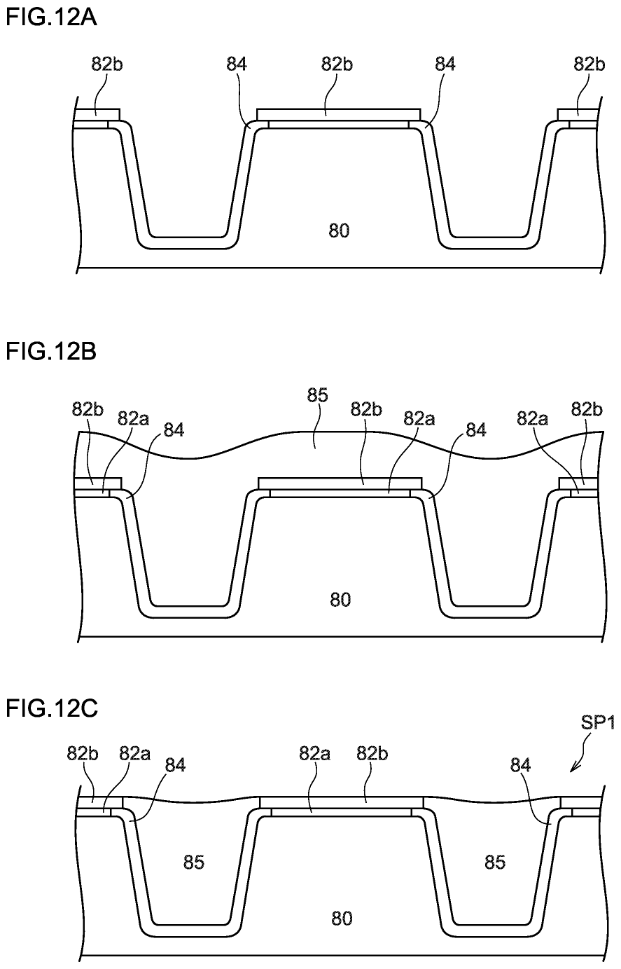

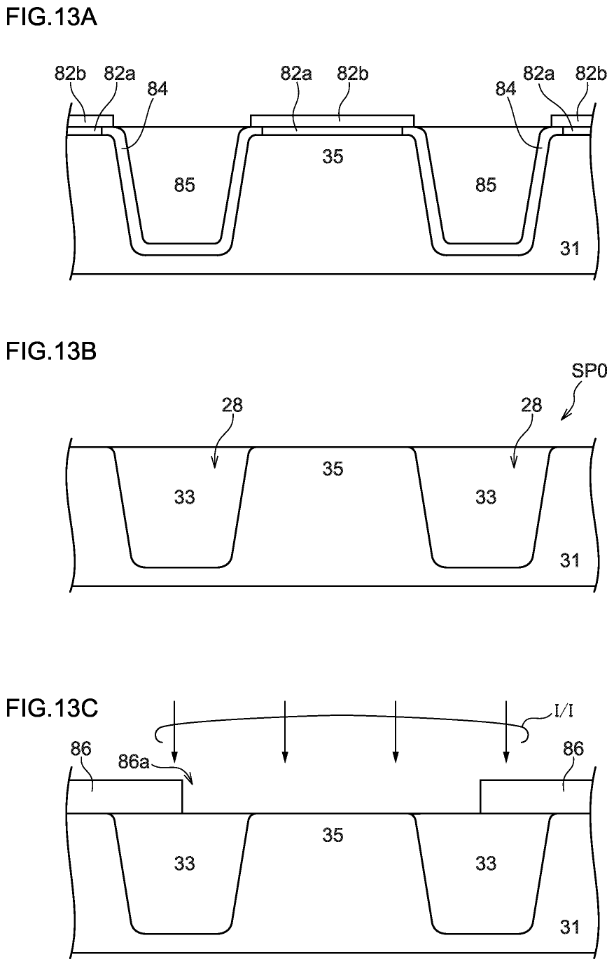

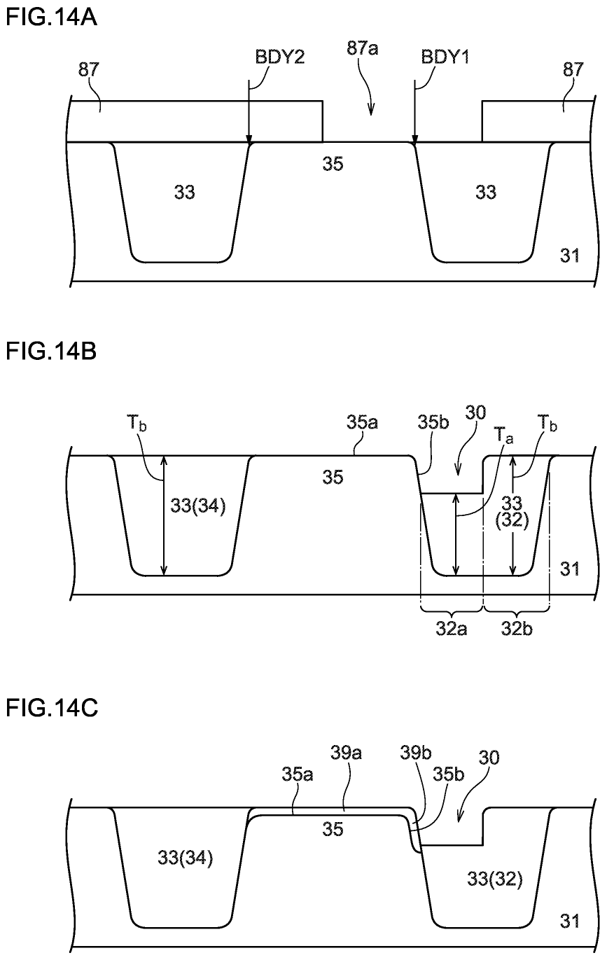

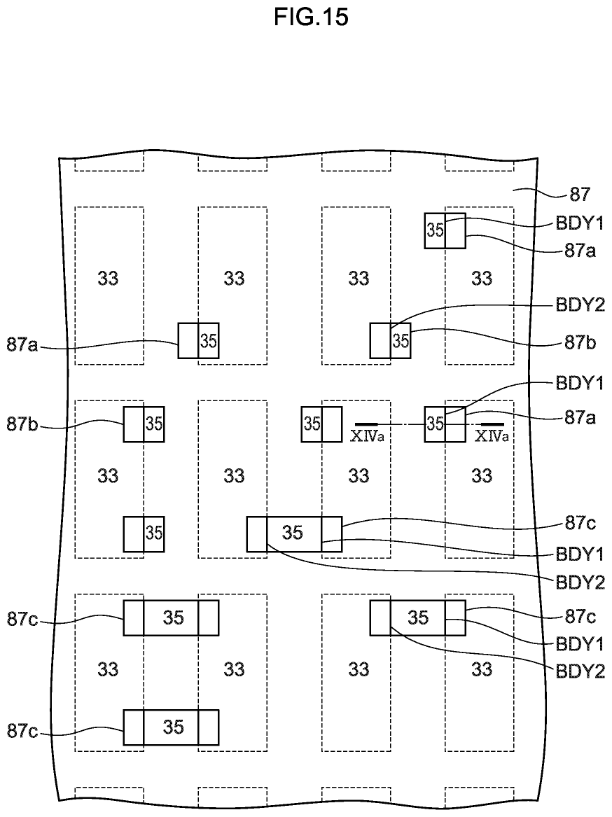

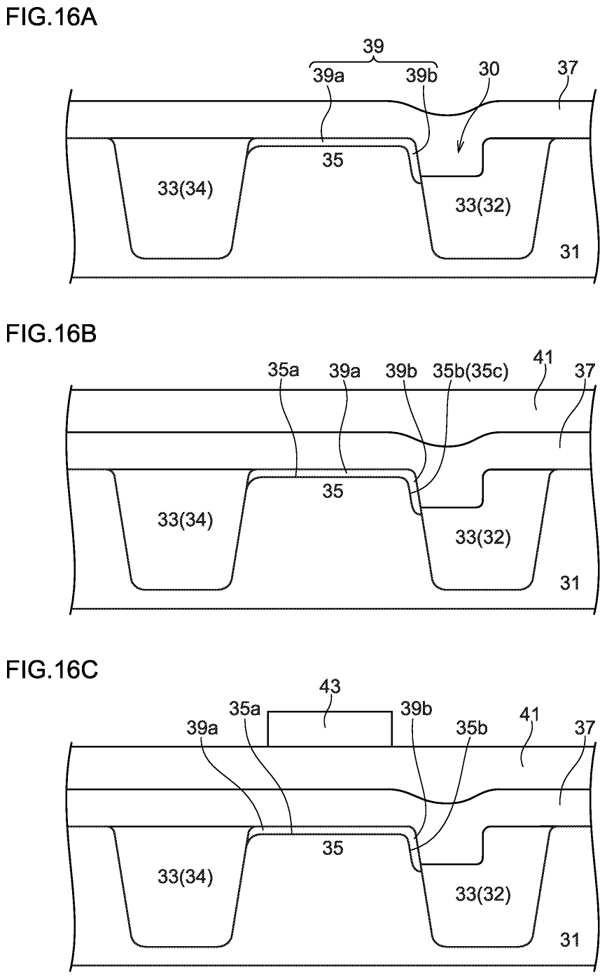

Now, principal steps in a method of fabricating the semiconductor memory device 13 are described with reference to FIG. 11A, FIG. 11B, FIG. 11C, FIG. 12A, FIG. 12B, FIG. 12C, FIG. 13A, FIG. 13B, FIG. 13C, FIG. 14A, FIG. 14B, FIG. 14C, FIG. 15, FIG. 16A, FIG. 16B and FIG. 16C. In the descriptions below, the reference symbols in the descriptions given above may be used for ease of understanding.

As illustrated in FIG. 11A, a semiconductor wafer 81 that is a silicon wafer is prepared. The silicon wafer may include a semiconductor region 80 with, for example, p-type conductivity. Insulating films, which are a silicon oxide film 82a and a silicon nitride film 82b, and a resist film 82c are formed in this order on the semiconductor wafer 81. The silicon oxide film 82a may be formed by, for example, oxidation of the semiconductor wafer 81. The silicon nitride film 82b may be deposited by a vapor phase growth technique. The resist film 82c may be applied by coating. The silicon oxide film 82a may be, for example, 10 nm thick, the silicon nitride film 82b may be, for example, 100 nm thick and the resist film 82c may be, for example, 700 nm thick.

As illustrated in FIG. 11B, the resist film 82c is exposed to light for pattern formation, and a mask 83 is formed. The mask 83 includes openings 83a at positions at which the depressions 28 for trenches are to be formed. Next, the mask 83 is used for etching of the silicon oxide film 82a, silicon nitride film 82b and semiconductor wafer 81, forming the depressions 28 in the semiconductor wafer 81. The etching may be implemented by anisotropic dry etching. Depths of the depressions 28 may be, for example, 0.2 μm, and widths of openings of the depressions 28 may be, for example, 0.3 μm. After the etching, the mask 83 is removed.

When required, as illustrated in FIG. 11C, a treatment with hydrogen fluoride is carried out after removal of the mask 83, and the semiconductor wafer 81 is cleaned. Undercuts 82d are formed in the silicon oxide film 82a.

When required, as illustrated in FIG. 12A, the semiconductor wafer 81 exposed in the depressions 28 is thermally oxidized after the removal of the mask 83, covering surfaces of the depressions 28 with a silicon oxide film 84.

As illustrated in FIG. 12B, after the surfaces of the depression 28 are thermally oxidized, silicon oxide 85 is deposited in the depressions 28 and on the silicon nitride film 82b by a chemical vapor phase growth technique. Thus, the depressions 28 are filled with the silicon oxide 85. The deposited silicon oxide 85 is an integral silicon oxide film extending from the silicon nitride film 82b and filling the depressions 28.

As illustrated in FIG. 12C, after the silicon oxide 85 is deposited, the deposited silicon oxide 85 and (when required) an upper side portion of the silicon nitride film 82b are removed by polishing with a chemical-mechanical polishing (CMP) technique, fabricating a substrate product SP1. Surface irregularities of the deposited silicon oxide 85 are flattened by this removal. Thus, the surface of the substrate product SP1 is substantially flat.

As illustrated in FIG. 13A, the silicon nitride film 82b remains on the semiconductor wafer 81 after the polishing, and an upper surface of the polished silicon oxide 85 is at the same level as an upper face of the silicon nitride film 82b. The silicon nitride film 82b is removed in a subsequent step. In order to avoid leaving protruding portions of the polished silicon oxide 85 after the removal of the silicon nitride film 82b, the polished silicon oxide 85 that is revealed in openings of the silicon nitride film 82b is etched in advance before the removal of the silicon nitride film 82b.

As illustrated in FIG. 13B, after this preparatory etching of the silicon oxide 85 at the depressions 28, insulating portions for the insulating regions 33 (32 and 34) are formed. Subsequently, the silicon nitride film 82b is removed by etching.

A substrate product SP0 is prepared by these steps. In the present exemplary embodiment, this preparation is carried out by fabricating the substrate product SP0 from the semiconductor wafer 81. The substrate product SP0 includes the semiconductor region 31 with the plural depressions 28 for shallow trench isolation (STI), and the plural insulating regions 33 that are respectively provided at the depressions 28 of the semiconductor region 31. The semiconductor region 31 includes the active regions 35, and the active regions 35 are provided between, of the insulating regions 33, the first insulating regions 32 and second insulating regions 34 that neighbor one another.

As illustrated in FIG. 13C, a dopant for adjusting the threshold values of memory transistors is introduced into the active regions 35 of the substrate product SP0. The dopant is, for example, a p-type dopant, and specifically may be boron. The introduction of the dopant may be carried out by, for example, an ion implantation (I/I) technique. More specifically, a thin oxide film is formed by thermal oxidation of the surface of the substrate product SP0, after which a mask 86 of resist is formed on the substrate product SP0 by photolithography. Dopant introduction areas are regulated by the mask 86 that has been formed. The ion implantation of the p-type dopant is applied to openings 86a of the mask 86. After the ion implantation, the mask 86 is removed. In the present exemplary embodiment, this is carried out for the active regions 35 of all the memory transistors.

As illustrated in FIG. 14A, after the ion implantation, a mask 87 of resist is formed on the principal surface of the substrate product SP0 by photolithography. The mask 87 includes openings 87a. The openings 87a are located above the active regions 35 at boundaries between the insulating regions 33 and the active regions 35 (either of BDY1 and BDY2), at which additional transistors are to be formed.

FIG. 15 is a plan view illustrating the mask 87 that is formed on the principal surface of the substrate product SP0. The mask 87 includes three types of openings 87a, 87b and 87c. The openings 87a are located above the boundaries BDY1 between insulating regions for the first insulating regions 32 and the active regions 35. The openings 87b are located above the boundaries BDY2 between insulating regions for the second insulating regions 34 and the active regions 35. The openings 87c are located above the boundaries BDY1 and boundaries BDY2. Thus, each opening (87a, 87b or 87c) of the mask 87 may be formed on at least one or other of a boundary BDY1 and a boundary BDY2.

As illustrated in FIG. 14B, the mask 87 is used to selectively remove the insulating regions 33 (32) of, for example, silicon oxide that are revealed in the openings (87a, 87b and 87c) from the semiconductor region 31 (the active regions 35). This removal may be conducted by, for example, reactive ion etching. The insulating regions 33 exposed in the openings (87a, 87b and 87c) are removed by this etching, forming the recess portions 30. As a result, the adjacent regions 32a and distant regions 32b are provided in the etched insulating regions 33. The recess portions 30 partially expose the side faces 35b of the active regions 35.

After the insulator of the insulating regions 33 is partially removed and the recess portions 30 are formed at the substrate product SP0, the gate insulation films 39 are formed at the active regions 35, as illustrated in FIG. 14C. The gate insulation films 39 are, for example, silicon oxide. More specifically, this silicon oxide is formed by thermal oxidation of the upper faces 35a of the active regions 35 and all the side faces 35b (and 35c) of the active regions 35.

As illustrated in FIG. 16A, after the formation of the gate insulation films 39, the gate electrodes 37 are formed on the active regions 35 and the insulating regions 33 (32 and 34) by deposition of polysilicon, photolithography and etching. The gate electrodes 37 that are formed extend over the upper faces of the active regions 35 and are provided over all the side faces 35b (and 35c) of the active regions 35. The gate electrodes 37 traverse each active region 35 in a direction from one to another of the first insulating region 32 and the second insulating region 34, and extend on the gate insulation films 39 above all the side faces 35b (and 35c) that are formed.

According to this fabrication method, areas of the insulating regions 33 that are removed using the openings (87a, 87b and 87c) in the mask 87 have a smaller thickness than a thickness of the insulating regions 33 away from the openings (87a, 87b and 87c). Therefore, each gate electrode 37 and gate insulation film 39 extend along both the upper face 35a of the corresponding active region 35 and one or both of the side face 35b and/or side face 35c formed at the active region 35. Thus, the side faces 35b and/or side faces 35c that are formed may operate as the additional transistors. According to this fabrication method, photolithography and anisotropic etching may be used to fabricate the additional transistors at one side and/or both sides of each active region 35.

As illustrated in FIG. 16B, after the gate electrodes 37 are formed, the interlayer insulating film 41 is grown on the substrate product by a chemical vapor phase growth technique. The interlayer insulating film 41 may be formed of, for example, a silicon-based inorganic insulator.

As illustrated in FIG. 16C, after the interlayer insulating film 41 is formed, photolithography and etching are used to form contact openings in the interlayer insulating film 41. Then, a metallizing process is applied to form the metal wiring layer 43.

As described above, an object according to the exemplary embodiment is to provide a semiconductor memory device with a structure that may provide any one of plural current characteristics without varying transistor width, a method for fabricating the semiconductor memory device, a semiconductor integrated circuit including a current source circuit and a bias source, and a semiconductor memory integrated circuit including the semiconductor integrated circuit and the semiconductor memory device.

The present disclosure is not limited by the exemplary embodiment described above and numerous modifications may be embodied within a scope not departing from the gist of the present disclosure. All these modifications are to be encompassed by the technical idea of the present disclosure.

What is claimed is:

1. A semiconductor memory device comprising:
a semiconductor region including a first active region for a first memory transistor and a plurality of depressions for trench isolation;
a plurality of insulating regions respectively provided at the depressions of the semiconductor region;
a first gate electrode that extends in a first direction from one to another of, among the plurality of insulating regions, a first insulating region and a second insulating region that are next to one another, the first gate electrode passing over the first active region; and
a first gate insulation film provided between the first gate electrode and the first active region,
wherein:
the first active region of the semiconductor region is provided between the first insulating region and the second insulating region;
at least one of the first insulating region or the second insulating region includes an adjacent region and a distant region;
the adjacent region is adjacent to the first active region under the first gate electrode;
the distant region is adjacent to the adjacent region under the first gate electrode;
the adjacent region is provided between the distant region and the first active region;
a thickness of the adjacent region is smaller than a thickness of the distant region;
the semiconductor region includes a first conductive region and a second conductive region provided between the first insulating region and the second insulating region; and
the first conductive region, the first active region and the second conductive region are arrayed in a second direction crossing the first direction.

2. The semiconductor memory device according to claim 1, wherein:
the semiconductor region further includes a second active region for a second memory transistor that is provided between the first insulating region and the second insulating region;
the semiconductor memory device further includes:
a second gate electrode that extends in the first direction above the second active region and passes over the second active region, and
a second gate insulation film provided between the second gate electrode and the second active region;
the semiconductor region further includes a third conductive region provided between the first insulating region and the second insulating region;
conductivity types of the first conductive region, the second conductive region and the third conductive region are different from a conductivity type of the first active region;
the second conductive region, the first active region, the first conductive region, the second active region and the third conductive region are arrayed in this order in the second direction;
the second conductive region and the third conductive region are connected to a reference potential line; and
the first conductive region is shared by the first memory transistor and the second memory transistor and is connected to a metal wiring layer.

3. The semiconductor memory device according to claim 1, wherein:
the thickness of the adjacent region of the first insulating region is smaller than the thickness of the distant region, and
the second insulating region under the first gate electrode is thicker than the adjacent region of the first insulating region.

4. The semiconductor memory device according to claim 1, wherein, in each of the first insulating region and the second insulating region, the thickness of the adjacent region is smaller than the thickness of the distant region.

5. The semiconductor memory device according to claim 1, wherein:
the insulating regions include a third insulating region neighboring the second insulating region;
the first insulating region, the second insulating region and the third insulating region are arrayed in this order in the first direction;
the semiconductor region further includes a third active region for a third memory transistor;
the first gate electrode extends in the first direction and passes over the third active region;
the semiconductor memory device further includes a third gate insulation film provided between the first gate electrode and the third active region;
the third insulating region includes an adjacent region and a distant region;
the adjacent region of the third insulating region is adjacent to the first active region under the first gate electrode,
the distant region of the third insulating region being adjacent to the adjacent region under the first gate electrode, and
the adjacent region being provided between the distant region and the first active region;
a thickness of the adjacent region of the third insulating region under the first gate electrode is smaller than a thickness of the distant region of the third insulating region; and
the second insulating region under the first gate electrode is thicker than the adjacent region of the third insulating region.

6. The semiconductor memory device according to claim 4, wherein:
the insulating regions include a fourth insulating region neighboring the first insulating region;
the semiconductor region further includes a fourth active region for a fourth memory transistor provided between the first insulating region and the fourth insulating region;
the first gate electrode extends in the first direction and passes over the fourth active region;
the semiconductor memory device further includes a fourth gate insulation film provided between the first gate electrode and the fourth active region;
the first insulating region includes a further adjacent region that is adjacent to the fourth active region under the first gate electrode;
the distant region of the first insulating region is provided under the first gate electrode between the adjacent region and the further adjacent region of the first insulating region;
the further adjacent region is provided between the distant region and the fourth active region; and
a thickness of the further adjacent region under the first gate electrode is smaller than a thickness of the distant region of the first insulating region.

7. The semiconductor memory device according to claim 1, wherein the adjacent region is one of:
a structure that traverses the first gate electrode in a direction from one to the other of the first conductive region and the second conductive region, or
a structure that extends from one of the first conductive region and the second conductive region and terminates directly under the first gate electrode.

8. A method for fabricating a semiconductor memory device, comprising:
preparing a substrate product that includes:
a semiconductor region including a plurality of depressions for trench isolation, and
a plurality of insulating regions respectively provided at the depressions of the semiconductor region,
the semiconductor region including an active region provided between, among the insulating regions, a first insulating region and a second insulating region that are next to one another;
forming a mask that includes an opening, on a principal surface of the substrate product;
removing an insulator of the insulating regions of the substrate product, using the mask;
after removing the insulator, forming a gate insulation film on the active region; and
after forming the gate insulation film, forming a gate electrode above the insulating regions and the active region,
wherein:
the opening of the mask is located above at least one of a first boundary between the active region and the first insulating region or a second boundary between the active region and the second insulating region;
removing the insulator of the substrate product includes partially removing the insulator at the opening of the mask and partially exposing a side face of the active region;
the gate insulation film is provided on the side face; and
the gate electrode traverses the active region in a direction from one to another of the first insulating region and the second insulating region and extends over the gate insulation film on the side face.

9. The method for fabricating a semiconductor memory device according to claim 8, wherein the mask covers the second boundary.

10. The method for fabricating a semiconductor memory device according to claim 8, wherein the opening of the mask is located above the first boundary and the second boundary.

11. A semiconductor integrated circuit comprising a current source circuit and a bias circuit, wherein:
the current source circuit includes at least one transistor, the transistor including:
a semiconductor region including a plurality of depressions for trench isolation,
a plurality of insulating regions respectively provided at the depressions of the semiconductor region, the plurality of insulating regions including a first insulating region and a second insulating region that neighbor one another,
an active region for the transistor that is provided between the first insulating region and the second insulating region,
a gate electrode that extends in a first direction from one to another of the first insulating region and the second insulating region, the gate electrode passing over the active region, and
a gate insulation film provided between the gate electrode and the active region;
at least one of the first insulating region or the second insulating region includes an adjacent region and a distant region;
the adjacent region is adjacent to the active region under the gate electrode;
the adjacent region is adjacent to the distant region under the gate electrode;
the adjacent region is provided between the distant region and the active region under the gate electrode;
a thickness of the adjacent region is smaller than a thickness of the distant region;
the semiconductor region includes a first conductive region provided between the first insulating region and the second insulating region, and a second conductive region provided between the first insulating region and the second insulating region;
the first conductive region, the active region and the second conductive region are arrayed in a second direction crossing the first direction; and
the bias source is connected to the gate electrode and provides a voltage to the gate electrode.
